(19) United States
(12) Patent Application Publication
(10) Pub. No.: US 2026/0255484 A1
(43) Pub. Date: Aug. 27, 2026

(54) FABRICATING ELECTRONIC DEVICES WITH METALLIZED INTERNAL STRUCTURES USING 3D PRINTING AND MICROFLUIDIC ELECTROLESS PLATING

(71) Applicant: ATOMIC SEMI INC., San Francisco, CA (US)

(72) Inventors: Zhenpeng XU, Daly City, CA (US); Sam ZELOOF, San Francisco, CA (US); Nate JENNINGS, Humble, TX (US)

(21) Appl. No.: 19/062,997

(22) Filed: Feb. 25, 2025

(51) Int. Cl. H05K 1/11; B01L 3/00; B33Y 10/00; B33Y 30/00; B33Y 80/00; H05K 3/18; H05K 3/42

(52) U.S. Cl. CPC H05K 1/115; B01L 3/502707; B33Y 10/00; B33Y 30/00; B33Y 80/00; H05K 3/182; H05K 3/187; H05K 3/422; H05K 2203/072

(57) ABSTRACT

A presently disclosed fabrication method may comprise: (1) using a 3D printer to print a device comprising hollow internal structures; and (2) applying an intermittent microfluidic electroless plating process to the device to coat the hollow internal structures with metal, wherein applying the intermittent microfluidic electroless plating process to the device comprises placing the device in a mold and while the device is in the mold: (a) introducing a first cycle of plating solution through an inlet of the mold, (b) pumping the first cycle of plating solution through the hollow internal structures; (c) pausing the pumping of the first cycle of plating solution; (d) introducing a second cycle of plating solution through the inlet of the mold to displace the first cycle of plating solution out an outlet of the mold; and (e) repeating steps (a)-(d) with subsequent cycles of fresh plating solution.

### TECHNICAL FIELD

The present disclosure relates generally to additive manufacturing. In particular, some implementations relate to fabricating electronic devices with metallized internal structures using 3D printing and microfluidic electroless plating.

### Description of Related Art

Additive manufacturing may refer to a process of fabricating an object layer-by-layer. 3D printing is an example of additive manufacturing. 3D printing may refer to a computerized process that fabricates a 3D object by depositing (or otherwise solidifying) successive layers of material. Inputs into a 3D printer may include computerized files (e.g., computer-aided design (CAD) files) that include pre-programmed representation(s) of an object to be printed/fabricated. Additive manufacturing/3D printing can enable greater design flexibility/customizability than alternative fabrication techniques. Relatedly, additive manufacturing/3D printing can be less expensive and quicker/more efficient than alternative fabrication techniques.

Stereolithography (sometimes referred to as vat photopolymerization) is an example of a 3D printing technology. Stereolithography may involve focusing a patterned image of ultraviolet (UV) radiation (e.g., emitted by a UV laser or light emitting diode (LED) laser) on to a vat of photopolymer resin. Because photopolymers are sensitive to UV radiation, the photopolymer resin may solidify/polymerize when exposed to UV radiation. Accordingly, the UV radiation may be used to “print” a pre-programmed representation of an object by solidifying/polymerizing the photopolymer resin in a layer-by-layer fashion.

### BRIEF DESCRIPTION OF THE DRAWINGS

The present disclosure, in accordance with one or more various examples, is described in detail with reference to the following figures. The figures are provided for purposes of illustration only and merely depict examples.

FIGS. 1A-1C illustrate a flowchart for fabricating electronic devices with metallized internal structures using 3D printing and microfluidic electroless plating, in accordance with various examples of the disclosed technology.

FIG. 2 illustrates an example device design, in accordance with various embodiments of the presently disclosed technology.

FIG. 3 illustrates an example 3D printer, in accordance with various embodiments of the presently disclosed technology.

FIG. 4 illustrates an example microfluidic cleaning device, in accordance with various examples of the disclosed technology.

FIG. 5 illustrates an example microfluidic electroless plating system, in accordance with various embodiments of the presently disclosed technology.

FIGS. 6A-6B illustrate perspective views of an example device design, in accordance with various embodiments of the presently disclosed technology.

FIG. 7 illustrates an example device design, in accordance with various embodiments of the presently disclosed technology.

FIG. 8 illustrates an example fabricated device, in accordance with various embodiments of the presently disclosed technology.

FIG. 9 illustrates an example computing component that may be used to implement various features of embodiments described in the present disclosure.

The figures are not exhaustive and do not limit the present disclosure to the precise form disclosed.

### DETAILED DESCRIPTION

Traditional fabrication methods for electronic devices, such as sequential layering processes, high-resolution patterning, and other conventional approaches, face challenges accommodating the rapidly growing demand for increasingly miniaturized and complex electronic devices. This is largely due to the lengthy research and development (R&D) cycles associated with these methods. Additionally, such methods often struggle to produce devices with intricate internal structures (e.g., substrates featuring complex internal geometries).

Accordingly, there is a significant need for innovative fabrication techniques that enable greater design flexibility, reduced costs, improved efficiency, and the capacity to rapidly prototype and fabricate electronics with intricate internal features.

As embodiments of the presently disclosed technology are designed in appreciation of, additive manufacturing (e.g., stereolithography) presents a promising new fabrication solution for electronics because it enables greater design flexibility and customizability than traditional methods. Relatedly, additive manufacturing/3D printing is generally less expensive and quicker/more efficient than traditional methods of fabricating electronic devices. In theory, additive manufacturing could also be used to fabricate complex, hollow internal structures directly into an electronic device being fabricated/printed.

However, conventional materials used for additive manufacturing generally lack the combination of mechanical robustness, high-temperature resistance (e.g., the ability to withstand temperatures above 150 degrees Celsius without significant deformation or degradation), and high precision printability required for electronic devices. For example, while stereolithography can facilitate high precision printability, conventional photopolymer resins used in stereolithography generally lack the mechanical robustness and high-temperature resistance required in electronic devices. While other conventional 3D printing techniques (e.g., extrusion-based methodologies like fused deposition modeling (FDM)) may utilize more robust/temperature resistant materials, these other conventional 3D printing techniques generally lack the high precision printability required for fabricating complex internal structures.

Moreover, metallization of complex, hollow internal structures (fabricated via additive manufacturing techniques or otherwise) remains a significant challenge. This is in part because existing metallization techniques often fail to deposit metal evenly or adequately within hollow internal structures. For example, common metallization techniques used in the field include chemical vapor deposition (CVD), physical vapor deposition (PVD), and electroplating. While CVD and PVD methods can produce high-quality coatings on exposed surfaces, they often face challenges in evenly coating internal surfaces, particularly in narrow or complex hollow structures. CVD and PVD are also generally expensive. Electroplating, on the other hand, requires a conductive surface, which is often absent in 3D-printed parts, making it difficult to achieve metal deposition. These limitations become more significant as the dimensions of internal structures decrease, resulting in inconsistent coatings or even leaving certain regions uncoated. Consequently, the combination of conventional metallization techniques with additive manufacturing has typically been confined to simple structures or surface metallization, leaving internal structures of printed objects unmetallized.

For the reasons stated above, conventional additive manufacturing and metallization techniques have generally been considered inadequate for fabricating electronic devices with complex/intricate internal structures.

Against this backdrop, the presently disclosed systems and methods combine innovative additive manufacturing techniques and materials with an innovative intermittent microfluidic electroless plating process to fabricate electronic devices with complex, metallized internal structures. As compared to existing technologies, such systems/methods may yield greater design flexibility, lower costs, greater efficiency, and improved capacity for fabricating and metallizing complex internal structures. For example, the presently disclosed systems/methods may be used to fabricate an electronic device (e.g., a printed circuit board) with complex, metallized internal microchannels (e.g., with 150 micrometer diameters or less).

As alluded to above, the presently disclosed systems/methods may involve an innovative intermittent microfluidic electroless plating process to coat hollow internal structures of a 3D-printed device with metal. The intermittent microfluidic electroless plating process may involve pumping fresh plating solution through the hollow internal structures in successive cycles. Each pumping phase of fresh plating solution may last approximately 10 seconds, followed by a pause of about 30 seconds before the next cycle begins. As an illustrative example, the overall intermittent cycling process may last between 30-90 minutes.

The presently disclosed intermittent microfluidic electroless plating process enhances metal deposition by leveraging periodic pauses in the plating process. For example, the intermittent cycling improves ion exchange and replenishment, ensuring a consistent supply of fresh plating solution throughout the hollow internal structures, even in long or complex geometries. This enhanced flow dynamics minimizes ion depletion, leading to more uniform metal deposition. As another example, the periodic flow helps prevent blockages in narrow sections by reducing buildup of plating material, ensuring unobstructed pathways for the plating solution. Moreover, the pauses provide sufficient time for the electrolyte to deposit metal onto the surface without disruption from active flow, further ensuring the continuity and stability of the deposited metal layer. By contrast, continuous flow can cause turbulence, disrupting the continuity of the forming metal layer in sensitive areas. At the opposite end of the spectrum, no flow (i.e., a static system) can result in uneven deposition due to reduced ion replenishment.

As described in greater detail below, the presently disclosed systems/methods may also involve additional fabrication steps that prepare surfaces of hollow internal structures of a 3D-printed device for metal plating. Such “pre-plating” steps may include: (1) etching the 3D-printed device to increase surface roughness of the hollow internal structures, and (2) repeated sensitization and activation of the (etched) 3D-printed device. These pre-plating steps can improve adhesion of the metal coating during the presently disclosed intermittent microfluidic electroless plating process and otherwise improve uniformity for metal deposition.

In some (but not all) implementations, the presently disclosed systems/methods may also utilize an innovative dual-curing resin that enables additive manufacturing of robust, high-temperature resistant, and high-precision structures (e.g., electronic devices with internal channels with diameters of 150 micrometers or less). Composition of the dual-curing resin may facilitate an initial UV curing to rapidly solidify the dual-curing resin from a low viscosity state when a device is being formed/printed—thus enabling high-precision printing. Composition of the dual-curing resin may also facilitate a second, thermal curing that significantly improves mechanical robustness and high-temperature resistance for the formed/printed device.

Unlike conventional photopolymer resins used in stereolithography that generally only facilitate UV curing, the dual-curing resin may comprise a thermal initiator (i.e., a compound that creates reactive species when exposed to thermal radiation) that enables the above-described second, thermal curing. This second/thermal curing can increase the cross-linking density of the polymer—thus improving the mechanical strength and temperature resistance of a resultant “dual-cured” device. As alluded to above, this improved mechanical strength and temperature resistance can make the “dual-cured” device suitable for electronic device applications that require high temperature resistance and robust mechanical strength. Moreover, the dual-curing resin may comprise additional compounds in particularly calibrated ratios (described in greater detail below) that produce a low viscosity resin (e.g., 100-250 cPs at 25 degrees Celsius) capable of rapid, high-precision solidification/polymerization during initial UV curing.

For example, in various implementations the dual-curing resin may comprise: (1) an acrylate oligomer; (2) one or more crosslinking agents; (3) one or more additives (e.g., silica); (4) a photoinitiator; (5) a UV blocker; and (6) the above-referenced thermal initiator.

The acrylate oligomer may serve as a base for the dual-curing resin and provide a structural back-bone contributing to the dual-curing resin's mechanical strength and high temperature resistance (after dual-curing). In various implementations, the acrylate oligomer may comprise 40-60% of the dual-curing resin by weight, and in more particular implementations, 47-53% of the dual-curing resin by weight. As used herein, acrylate may refer to esters derived from acrylic acid capable of participating in free-radical polymerization reactions. An oligomer may refer to a molecule comprising repeating units derived from smaller molecules/monomers. Accordingly, an acrylate oligomer may refer to an oligomer comprising repeating units of acrylate.

The one or more crosslinking agents (sometimes referred to as auxiliary crosslinking agents) can improve crosslinking density of the dual-curing resin. By improving crosslinking density of the dual-curing resin, the one or more crosslinking agents can further enhance the mechanical strength and thermal stability of the dual-curing resin (after dual-curing). In various implementations, the one or more crosslinking agents may comprise 12-20% of the dual-curing resin by weight, and in more particular implementations, 14-18% of the dual-curing resin by weight. As used herein, a crosslinking agent may refer to a molecule/compound comprising two or more reactive ends for chemically attaching to functional groups on other molecules/compounds (e.g., Ethoxylated Trimethylolpropane Triacrylate, Urethane Dimethacrylate, etc.).

The one or more additives (e.g., silica, Acryloyl Morpholine, etc.) can modify the rheological properties of the dual-curing resin, and like the one or more cross-linking agents, contribute to enhanced mechanical strength and thermal stability after dual-curing. For example, silica can act as a rheology modifier that helps control viscosity of the dual-curing resin, thus reducing/preventing sedimentation or phase separation. Acryloyl Morpholine can function as a reactive diluent that reduces viscosity of the dual-curing resin. As alluded to above, embodiments may tune viscosity of the dual-curing resin to as low as 100-250 cPs at 25 degrees Celsius. This low viscosity can facilitate high-precision printing/UV curing of the dual-curing resin. In various implementations, the additives may comprise 20-40% of the dual-curing resin by weight, and in more particular implementations, 27-33% of the dual-curing resin by weight.

The photoinitiator can enable UV curing for the dual-curing resin, facilitating rapid and high-precision polymerization/solidification during 3D printing. In various implementations, the photoinitiator may comprise 1-3% of the dual-curing resin by weight, and in more particular implementations, 1.5-2.5% of the dual-curing resin by weight. As used herein, a photoinitiator (e.g., Diphenyl(2,4,6-trimethylbenzoyl)-phosphine oxide) may refer to a molecule/compound that, when exposed to electromagnetic radiation (e.g., UV radiation), absorbs energy and generates reactive species (e.g., free radicals or ions) to initiate the polymerization process.

The UV blocker can further enhance printing precision by controlling the penetration depth of UV radiation and minimizing unwanted light scattering. In various implementations, the UV blocker may comprise 0.5% or lower of the dual-curing resin by weight, and in more particular implementations, 0.3% or lower of the dual-curing resin by weight. As used herein, a UV blocker (e.g., Sudan I) may refer to a molecule/compound that absorbs/blocks UV radiation to regulate the UV curing process and improve the overall accuracy/precision of a printed structure.

As alluded to above, the thermal initiator can facilitate a second, thermal curing that enhances the mechanical strength and temperature resistance of the “dual-cured” resin. In various implementations, the thermal initiator may comprise 0.5% or lower of the dual-curing resin by weight, and in more particular implementations, 0.1% or lower of the dual-curing resin by weight. As used herein, a thermal initiator (e.g., Dicumyl Peroxide) may refer to a molecule/compound that decomposes upon exposure to heat, thus generating reactive species (e.g., free radicals) that further propagate the polymerization process during thermal curing.

As alluded to above, the presently disclosed dual-curing resin may exhibit favorable properties for electronic devices, and other devices/applications that require high temperature resistance, robust mechanical strength, and high precision feature resolution.

This is because, once dual-cured, the dual-curing resin may exhibit robust mechanical strength and high temperature resistance. For example, depending on formulation, the dual-curing resin may withstand temperatures up to 150 degrees Celsius, 200 degrees Celsius, 250 degrees Celsius, or even 300 degrees Celsius without significant deformation or degradation. Accordingly, the dual-curing resin and associated additive manufacturing methods may be better suited for electronic devices that require robust mechanical strength and high temperature resistance than conventional photopolymer resins used in stereolithography. As alluded to above, many of these conventional photopolymer resins exhibit much lower temperature resistance (e.g., 60 to 90 degrees Celsius) than the presently disclosed dual-curing resin. While some conventional photopolymer resins can exhibit higher temperature resistance than other conventional photopolymer resins (e.g., up to 200-250 degrees Celsius post-curing), such photopolymer resins are generally brittle making them less suitable for devices/applications that require robust mechanical strength (e.g., electronics applications such as printed circuit board). As used herein, temperature resistance up to a particular temperature (e.g., 300 degrees Celsius) may refer to an ability of a material to withstand the particular temperature without significant deformation or degradation.

As another example, the dual-curing resin can be printed to form hollow internal structures at high resolution (e.g., 150 micrometers or smaller) due in part to its low viscosity (e.g., 100-250 cPs at 25 degrees Celsius) and contributions from the photoinitiator and UV blocker-which facilitate a rapid and precise UV curing. Accordingly, the dual-curing resin (and associated additive manufacturing methods) may be used to fabricate devices with higher resolution features than many traditional additive manufacturing methods (e.g., extrusion-based methodologies such as fused deposition modeling (FDM), powder bed fusion, etc.).

Relatedly, the disclosed dual-curing resin can make it practical to directly print complex, hollow internal structures within a device (in some cases with resolution of 150 micrometers or less), which is not generally achievable with traditional fabrication methods (e.g., conventional multilayer assembly, metal patterning, and sequential build-up processes). This approach can also enable the integration of intricate features (e.g., embedded sensors or other small devices) within the device, offering new design possibilities and enhanced functionality for electronic devices.

Embodiments of the presently disclosed technology will now be described in greater detail in conjunction with the following FIGs.

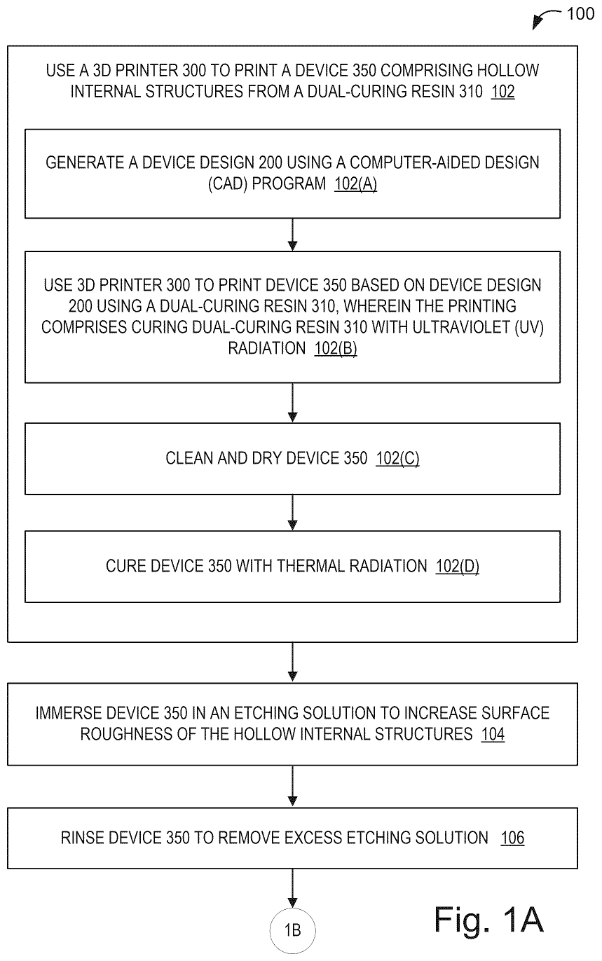

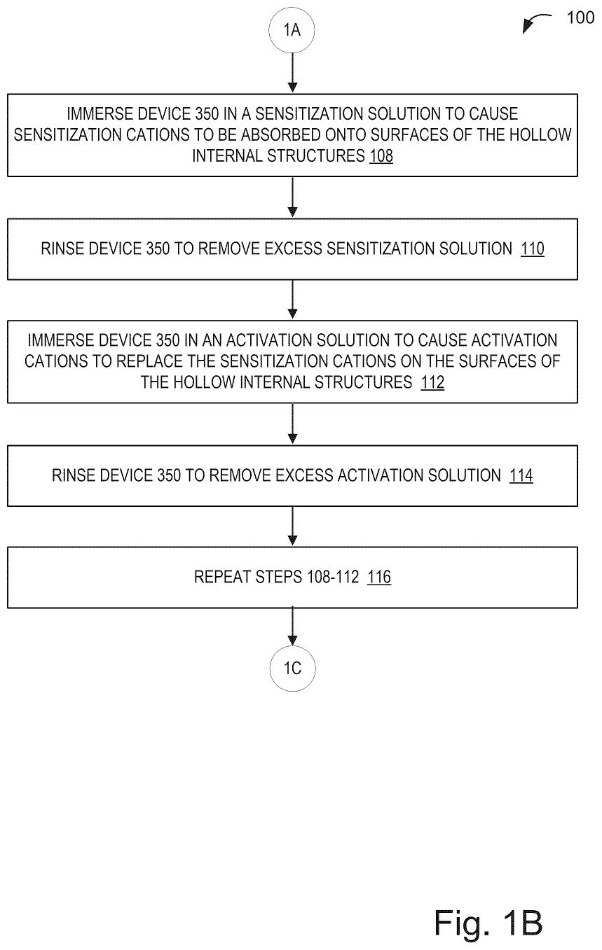

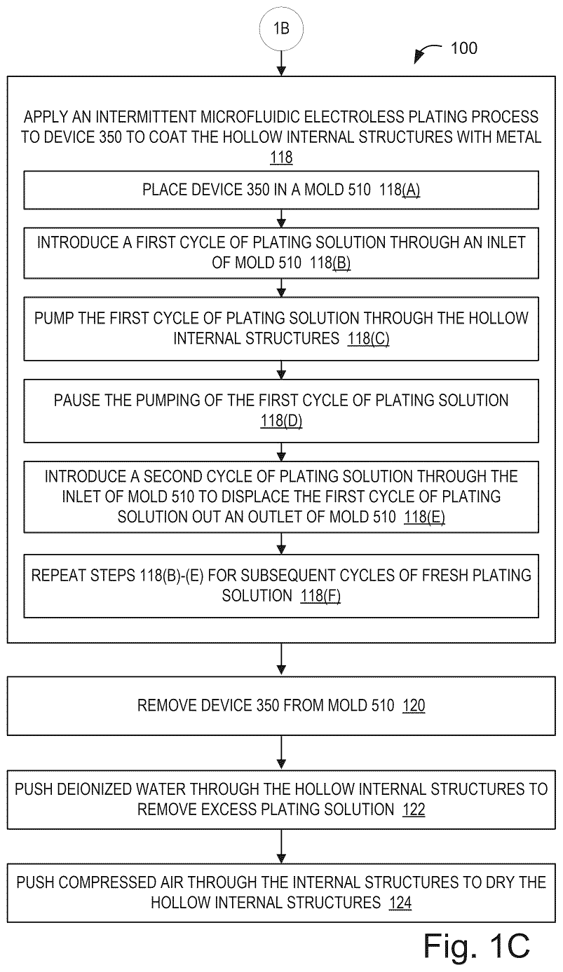

FIGS. 1A-1C illustrate a flowchart 100 for fabricating electronic devices with metallized internal structures using 3D printing and microfluidic electroless plating, in accordance with various examples of the presently disclosed technology.

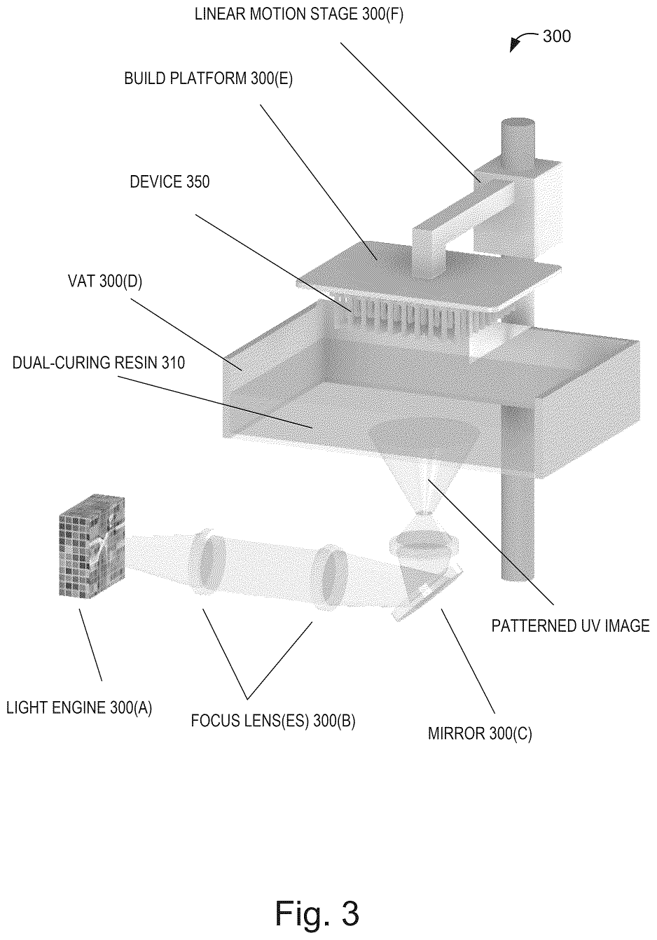

As depicted, step 102 of the fabrication method may involve using a 3D printer 300 to print a device 350 comprising hollow internal structures from a dual-curing resin 310. Examples of 3D printer 300, device 350, and dual-curing resin 310 are depicted in FIG. 3.

As depicted in FIG. 1A, using 3D printer 300 to print device 350 may comprise sub-steps 102(A)-102(D).

Sub-step 102(A) may involve generating a device design 200 (e.g., a micro-structured device) using a 3D CAD software.

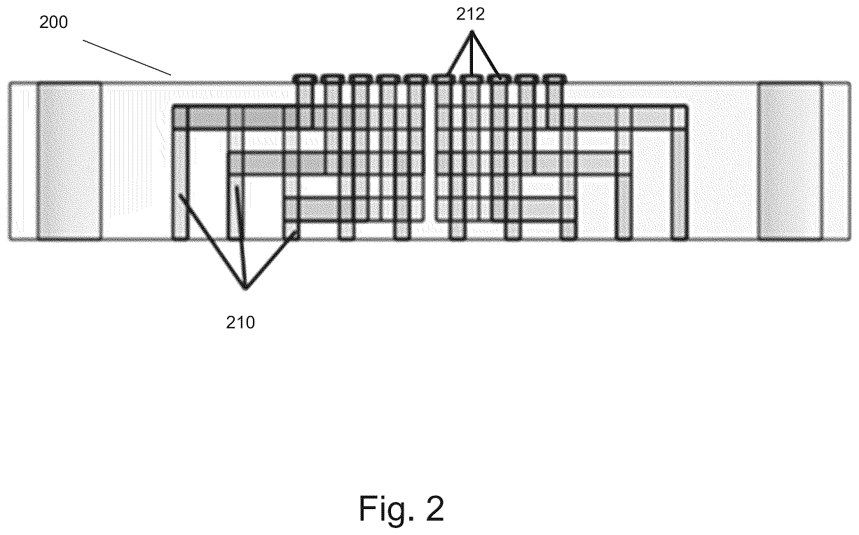

An example for device design 200 is illustrated in FIG. 2. As depicted, device design 200 may comprise hollow internal structures 210 (e.g., hollow microchannels) that connect the top and bottom of device design 200. When plated with conductive material, hollow internal structures 210 can facilitate electrical interconnections through device design 200. In certain implementations, device design 200 may also comprise micro-bumps 212 that provide electrical connections to hollow internal structures 210 (once plated with conductive material).

Benefiting from the unique capabilities of additive manufacturing, design parameters of device design 200 can be quickly adjusted, allowing for rapid iteration and optimization based on specific analytical requirements. This can significantly reduce development time and accelerate the research-to-application transition for new diagnostic or analytical methods.

Furthermore, the flexibility of additive manufacturing can permit the creation of hollow internal structures 210 in many shapes or geometries which are generally infeasible to fabricate with traditional fabrication methods for electronic devices. This design flexibility enables optimized routing and connection paths for hollow internal structures 210, which can enhance overall performance and reliability of device design 200. The ability to design and fabricate complex and custom geometries for hollow internal structures 210, along with other features of device design 200, can provide additional advantages as well. For example, such customization allows for the integration of specialized functionalities (e.g., embedded small devices or sensors) that enhance the versatility, capabilities, and performance of device design 200.

Referring again to FIG. 1A, sub-step 102(B) may involve using 3D printer 300 (e.g., a stereolithography printer) to print device 350 based on device design 200 using dual-curing resin 310.

An example of 3D printer 300 and dual-curing resin 310 are depicted in FIG. 3. Dual-curing resin 310 may comprise the dual-curing resin described above. As depicted, 3D printer 300 may be an example of a stereolithography printer. For example, 3D printer 300 may comprise a liquid-crystal display (LCD) mask resin printer, a laser-based stereolithography printer, a digital light processing (DLP) printer, etc.

As alluded to above, 3D printer 300 may use various software-aided techniques to print device 350 based on device design 200. For example, device design 200 (which may be stored as a 3D CAD file) may be converted into a .stl file. The .stl file may then be sliced into 2D images. The sliced .stl file may then be imported to 3D printer 300. 3D printer 300 may then fabricate/print device 350 based on device design 200 in a layer-by-layer manner.

As depicted, 3D printer 300 may comprise a light engine 300(A), which in certain implementations may comprise a UV laser or a UV LED. Light engine 300(A) may emit a particularly patterned beam of UV radiation corresponding to layers of device design 200. For example, each respective patterned beam of UV radiation may correspond to a respective 2D slice of device design 200.

As depicted, 3D printer 300 may also comprise one or more lens(es) 300(B), a mirror 300(C), a vat 300(D), a build platform 300(E), and a linear motion stage 300(F). Here, the one or more lens(es) 300(B) may focus a respective patterned beam of UV radiation onto mirror 300(C). Mirror 300(C) may then reflect the focused patterned beam of UV radiation into/onto vat 300(D). Vat 300(D) may contain dual-curing resin 310 in its low viscosity state. Build platform 300(E) may support the formation of a printed device (e.g., device 350). Linear motion stage 300(F) may move build platform 300(E) vertically as successive layers are printed.

As described above, a photoinitiator in dual-curing resin 310 may create a reactive species (e.g., free radicals or ions) when exposed to the focused patterned beam of UV radiation, causing a respective layer of dual-curing resin 310 to solidify/polymerize into a pattern reflecting the patterned beam of UV radiation. As depicted, successive layers of solidified/polymerized dual-curing resin 310 may form device 350 (i.e., corresponding to a fabricated version of device design 200) onto build platform 300(E).

As alluded to above, embodiments can print precision features (e.g., hollow internal structures) with sub-150 micrometer resolution by intelligently tuning: (1) parameters of 3D printer 300 (e.g., UV radiation exposure times, UV radiation intensity, layer thicknesses, etc.); and (2) composition of dual-curing resin 310 (e.g., concentration of the UV blocker and photoinitiator). Relatedly, multilayered hollow internal structures of device 350 can be printed/fabricated in a single printing step, eliminating/reducing the need for complex assembly or multiple fabrication stages. In this way, the presently disclosed fabrication method can present an advantage over traditional fabrication methods (e.g., soft lithography, hot embossing, and injection molding) which would typically require multiple complex steps (e.g., master mold creation, polymer casting and surface treatment, etc.) to create similar features.

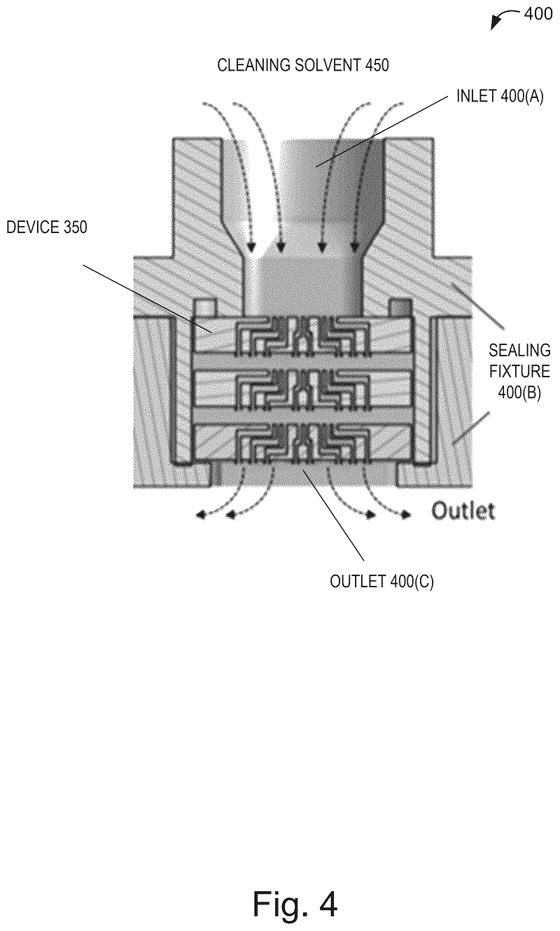

Referring again to FIG. 1A, after device 350 has been formed and UV cured, sub-step 102(C) may involve cleaning and drying device 350. As depicted in FIG. 4, in certain implementations this cleaning process may involve placing device 350 into a specially designed microfluidic device 400.

As depicted, microfluidic device 400 may provide a sealable environment for cleaning the hollow internal structures of device 350. As depicted, sealing fixture(s) 400(B) of microfluidic device 400 may facilitate such sealing.

When device 350 is sealed within microfluidic device 400, a cleaning solvent 450 (e.g., isopropyl alcohol (IPA)) may be introduced through an inlet 400(A) of microfluidic device 400. Microfluidic device 400 may then push cleaning solvent 450 through the hollow internal structures of device 350 to flush/remove residual material in the hollow internal structures. Here, flow rates for cleaning solvent 450 may be carefully controlled by controlling conditions at inlet 400(A) and an outlet 400(C) of microfluidic device 400.

The above-described cleaning process can ensure the small/intricate hollow internal structures of device 350 are fully cleaned of residual materials, which can be difficult to achieve using conventional cleaning methods.

After cleaning, device 350 can be dried within microfluidic device 400 using compressed air to remove cleaning solvent 450.

Referring again to FIG. 1A, sub-step 102(D) may involve curing the cleaned/dried device 350 with thermal radiation. As alluded to above, such thermal curing may be facilitated by a thermal initiator in dual-curing resin 310 (from which device 350 is formed) that creates reactive species when exposed to thermal radiation—thus furthering propagating the polymerization process for dual-curing resin 310.

As alluded to above, conventional stereolithography techniques typically only involve UV curing. Accordingly, by thermal curing embodiments can achieve higher mechanical strength and greater temperature resistance than conventional stereolithography techniques.

For example, subsequent rounds of UV curing after a structure is formed may primarily harden an outer shell of the structure, which can lead to weak internal areas. This is in part because, in the case of opaque resins, UV radiation cannot easily penetrate and cure internal structures.

By contrast, the presently disclosed thermal curing can better solidify an interior of the structure, making the structure stronger and more reliable. This is especially true for designs with complex, hollow internal structures.

In certain implementations, the thermal curing may involve placing device 350 in a thermal curing mold during (and in some implementations, for a period after) the thermal curing process. This can help maintain the shape of device 350 and prevent warping (in certain cases, stereographically printed structures may be susceptible to warping during/after curing).

After device 350 has been thermal cured, steps 104-116 may be implemented to prepare device 350 for metal plating at step 118 (depicted in FIG. 1C).

For example, step 104 may involve immersing device 350 in an etching solution to increase surface roughness of the hollow internal structures of device 350. Here, the increased surface roughness caused by the etching can improve bonding between plated metal and the surfaces of the hollow internal structures (comprising the “dual-cured” resin 310). In other words, the increased surface roughness can help a metal layer adhere more securely, providing more reliable electrical pathways.

The etching solution may comprise various types of etching solutions, including an alkaline solution.

Step 106 may involve rinsing device 350 to remove excess etching solution. In certain implementations, deionized water may be used for such rinsing.

As depicted in FIG. 1B, step 108 may involve immersing device 350 in a sensitization solution to cause sensitization cations to be absorbed onto surfaces of the hollow internal structures. Such absorbed sensitization cations can form a layer that facilitates subsequent activation at step 112. Namely, this layer of absorbed sensitization cations can prepare the surfaces of the hollow internal structures to interact with an activating agent more effectively.

In various implementations, the sensitization solution may comprise a SnCl₂ solution, and the sensitization cations may comprise Sn²⁺ cations. In certain of these implementations, concentration of SnCl₂ in the SnCl₂ solution may be between 0.1 M and 0.2 M for enhanced results.

Use of SnCl₂ solution as a sensitization solution can provide certain advantages, including: (1) acting as a strong sensitization agent: Sn²⁺ cations can effectively adhere to non-metallic surfaces and create a base layer that facilitates the deposition of catalytic particles, such as Pd²⁺, during activation; (2) high compatibility: SnCl₂ is compatible with a wide range of materials, including polymers, which makes it suitable for use on 3D-printed devices with complex geometries; and (3) promotion of uniform coverage: particularized concentrations of SnCl₂ solution can ensure uniform distribution of the Sn²⁺ cations, thereby enhancing metal deposition uniformity in both internal and external features of 3D-printed devices.

Notwithstanding above, other sensitization solutions may be used instead of an SnCl₂ solution. Examples may include TiCl₃, other metal chlorides such as ZrCl₄, and AgNO₃.

After sensitization, step 110 may involve rinsing device 350 to remove excess sensitization solution. As alluded to above, deionized water may be used for such rinsing.

Step 112 may then involve immersing device 350 in an activation solution to cause activation cations to replace the sensitization cations on the surfaces of the hollow internal structures of device 350. Here, the deposited activation cations can act as catalytic sites for the intermittent microfluidic electroless plating process of step 118. These catalytic sites can help initiate the plating reaction during the intermittent microfluidic electroless plating process of step 118—thus improving uniformity for metal deposition.

In various implementations, the activation solution may comprise a PdCl₂ solution and the activation cations may comprise Pd²⁺ cations. In certain of these implementations, concentration of PdCl₂ in the PdCl₂ solution may be between 0.001 M and 0.005 M for enhanced results.

As depicted, step 114 may involve rinsing device 350 to remove excess activation solution. Step 116 may then involve repeating steps 108-112. The post-activation rinsing of step 114 may not be repeated to improve the catalytic effect of the deposited activation cations during the intermittent microfluidic electroless plating process of step 118.

Here, repeating the sensitization and activation of steps 108-112 presents multiple advantages outlined below.

For example, repeating the sensitization and activation of steps 108-112 can improve the deposition uniformity of the sensitization and activation cations, particularly within hard-to-reach places like the hollow internal structures of device 350. More uniform coating of sensitization and activation cations can improve uniformity for metal deposition during the intermittent microfluidic electroless plating process of step 118.

Repeating the sensitization and activation of steps 108-112 can similarly improve adhesion for the sensitization and activation cations thus creating a more robust and uniform layer of catalytic sites. A more robust layer of catalytic sites can enhance the adhesion of plated metal to hollow internal structures of device 350, leading to improved quality and reliability of the final plated surfaces.

Repeating the sensitization and activation of steps 108-112 can also help to eliminate any gaps or inconsistencies in the sensitization or activation, minimizing defects such as uneven plating, which can lead to poor conductivity, especially in intricate internal geometries.

In sum, for devices with complex internal structures (such as device 350), repeated sensitization and activation can increase the likelihood that all areas of internal surfaces are properly prepared for metal plating.

Referring now to FIG. 1C, after the “pre-plating” processes of steps 108-116, step 118 may involve applying an intermittent microfluidic electroless plating process to device 350 to coat its hollow internal structures with metal. As depicted, step 118 may comprise sub-steps 118(A)-118(F).

As alluded to above (as reflected in step 118), the presently disclosed intermittent microfluidic electroless plating process may involve pumping fresh plating solution through the hollow internal structures of device 350 in successive cycles. Each pumping phase of fresh plating solution may last approximately 10 seconds, followed by a pause of about 30 seconds before the next cycle begins. As an illustrative example, the overall intermittent microfluidic electroless plating process may last between 30-90 minutes. However, it may be appreciated that the intermittent microfluidic electroless plating process may have a longer or shorter duration depending on application. For example, thicker metal coatings may be useful for applications that require higher current-carrying capacity or greater mechanical robustness. Accordingly, a longer duration for the intermittent microfluidic electroless plating process (e.g., over 90 minutes) may be suitable for such applications.

As alluded to above, the presently disclosed intermittent microfluidic electroless plating process (as reflected in step 118) enhances metal deposition by leveraging periodic pauses in the plating process. For example, the intermittent cycling improves ion exchange and replenishment, ensuring a consistent supply of fresh plating solution throughout the hollow internal structures, even in long or complex geometries. This enhanced flow dynamics minimizes ion depletion, leading to more uniform metal deposition. As another example, the periodic flow helps prevent blockages in narrow sections by reducing buildup of plating material, ensuring unobstructed pathways for the plating solution. Moreover, the pauses provide sufficient time for the electrolyte to deposit metal onto the surface without disruption from active flow, further ensuring the continuity and stability of the deposited metal layer. By contrast, continuous flow can cause turbulence, disrupting the continuity of the forming metal layer in sensitive areas. At the opposite end of the spectrum, no flow (i.e., a static system) can result in uneven deposition due to reduced ion replenishment.

Referring again to FIG. 1C, sub-step 118(A) may involve placing device 350 in a mold 510. Accordingly, subsequent sub-steps 118(B)-118(F) may all be performed while device 350 is within mold 510.

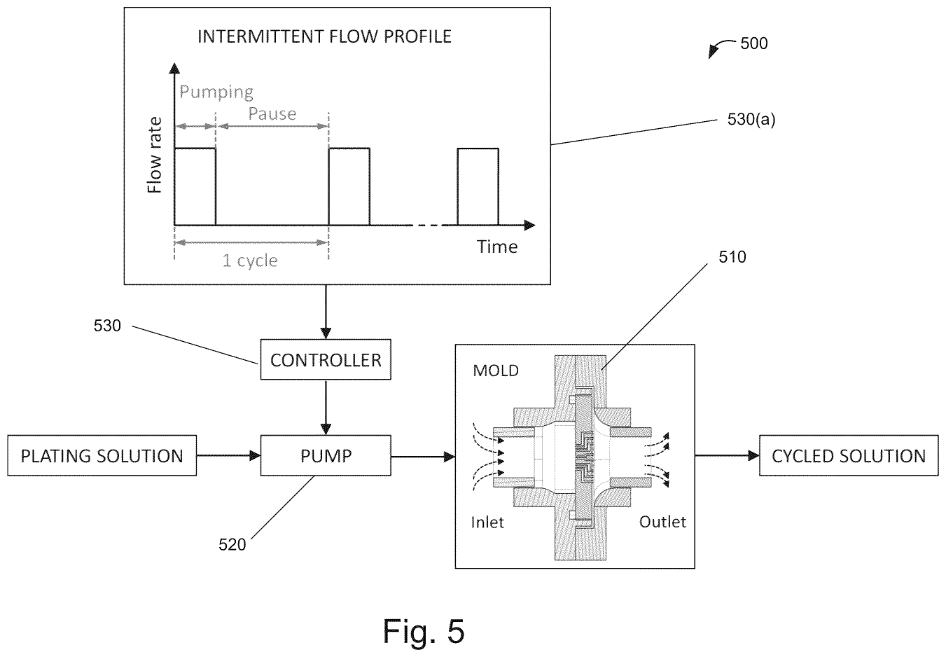

Mold 510 may be part of a microfluidic electroless plating system 500 depicted in FIG. 5. As depicted in FIG. 5, microfluidic electroless plating system 500 may also comprise a pump 520 (e.g., a peristaltic pump) fluidly connected to mold 510, and a controller 530 communicatively connected to pump 520, and in some implementations, the inlet and outlet of mold 510. Accordingly, in certain implementations, controller 530 may be configured to perform sub-steps 118(B)-118(F) automatically. For example, controller 530 may comprise one or more processors and memory storing machine-readable instructions that, when executed by the one or more processors, cause controller 530 to control pump 520 in accordance with intermittent flow profile 530.

Mold 510 may be designed to tightly enclose device 350, and more particularly, to tightly enclose the hollow internal structures of device 350. Such a tight seal can increase the likelihood that cycled plating solution flows smoothly through these confined spaces without leakage.

In various implementations, mold 510 may have an adjustable or modular design to accommodate devices of varying sizes and geometries, enhancing flexibility for different applications.

In certain implementations, mold 510 could further comprise integrated temperature control mechanisms to maintain optimal plating conditions, further enhancing uniformity for metal deposition. In some of these implementations, controller 530 may be configured to control these temperature control mechanisms automatically.

Referring again to FIG. 1C, sub-step 118(B) may involve introducing a first cycle of plating solution through an inlet of mold 510.

Accordingly, sub-step 118(C) may then involve pumping the first cycle of plating solution through the hollow internal structures of device 350. As alluded to above, in certain implementations pumping of the first cycle may last approximately 10 seconds. More generally, pumping of the first cycle may last between 5 and 30 seconds, depending on the preset flow rate and size of the device.

In certain implementations, composition, pH and temperature of the plating solution may be calibrated to enhance deposition quality.

For example, the plating solution may comprise a carefully balanced mix of a metal source (e.g., CuSO₄ for copper), a reducing agent (e.g., glyoxylic acid), and chelating agents (e.g., Ethylenediaminetetraacetic acid (EDTA)) to increase the likelihood of stable ion release and consistent metal deposition throughout the plating process. Moreover, in some implementations the plating solution may comprise inhibitor compounds (e.g., 2,2′-bipyridine) to regulate reaction rate, further enhancing metal deposition uniformity throughout the hollow internal structures and preventing/reducing excessive buildup in certain areas.

pH of the plating solution may also be adjusted to a particular value, which could be either alkaline or acidic, depending on the application and the materials being plated. For example, in the case of electroless copper plating, the pH is typically adjusted to an alkaline range of 12.0 to 13.0. Conversely, for electroless nickel plating, the pH is commonly maintained in an acidic range of 4.0 to 6.0.

While the description above is provided as an illustrative example of composition/pH for the plating solution, it may be appreciated that other compositions/pH values may be used depending on application. In general, the presently disclosed intermittent microfluidic electroless plating process (along with microfluidic electroless plating system 500) can be used with various types of plating solutions.

Referring again to FIG. 1C, sub-step 118(D) may involve pausing the pumping of the first cycle of plating solution. In certain implementations, this may comprise pausing the pumping of the first solution for between 10 and 60 seconds. As described above, the presently disclosed intermittent microfluidic electroless plating process enhances metal deposition by leveraging periodic pauses in the plating process. For example, the intermittent cycling improves ion exchange and replenishment, ensuring a consistent supply of fresh plating solution throughout the hollow internal structures, even in long or complex geometries. This enhanced flow dynamics minimizes ion depletion, leading to more uniform metal deposition. As another example, the periodic flow helps prevent blockages in narrow sections by reducing buildup of plating material, ensuring unobstructed pathways for the plating solution. Moreover, the pauses provide sufficient time for the electrolyte to deposit metal onto the surface without disruption from active flow, further ensuring the continuity and stability of the deposited metal layer. By contrast, continuous flow can cause turbulence, disrupting the continuity of the forming metal layer in sensitive areas. At the opposite end of the spectrum, no flow can result in uneven deposition due to reduced ion replenishment.

Sub-step 118(E) may involve introducing a second cycle of plating solution through the inlet of mold 510 to displace the first cycle of plating solution out an outlet of mold 510. As alluded to above, in some implementations this may be achieved by controller 530 controlling the inlet and outlet of mold 510.

Sub-step 118(F) may then involve repeating steps 118(B)-(E) for subsequent cycles of fresh plating solution.

As alluded to above, depending on application, the cycling may continue for 30-90 minutes.

Upon completion of the intermittent microfluidic electroless plating process of step 118, step 120 may involve removing (the now plated) device 350 from mold 510. Step 122 may then involve pushing deionized water through the plated hollow internal structures to remove excess plating solution. Step 124 may then involve pushing compressed air through the plated hollow internal structures to dry the plated hollow internal structures. In certain implementations, these rinsing and drying steps may be performed within a sealable environment, such as microfluidic device 400.

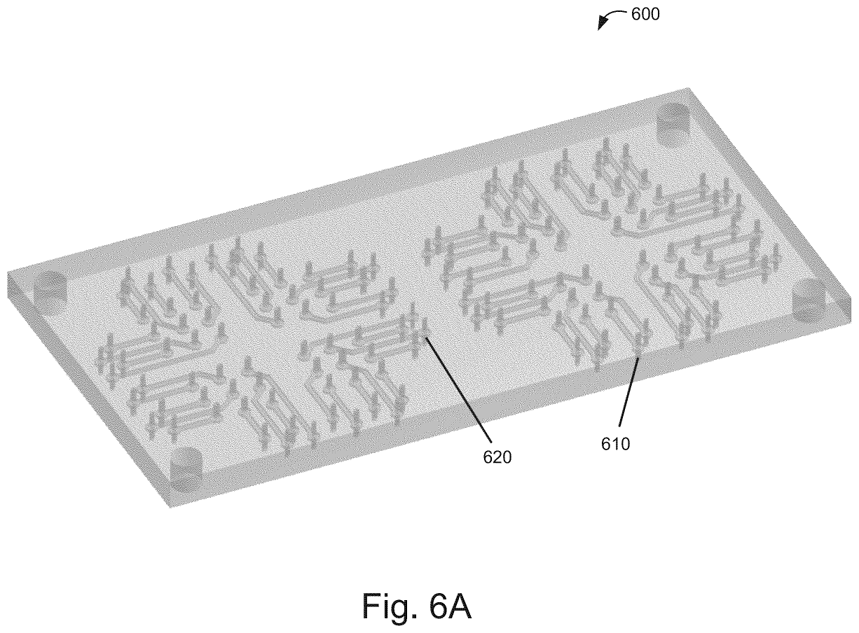

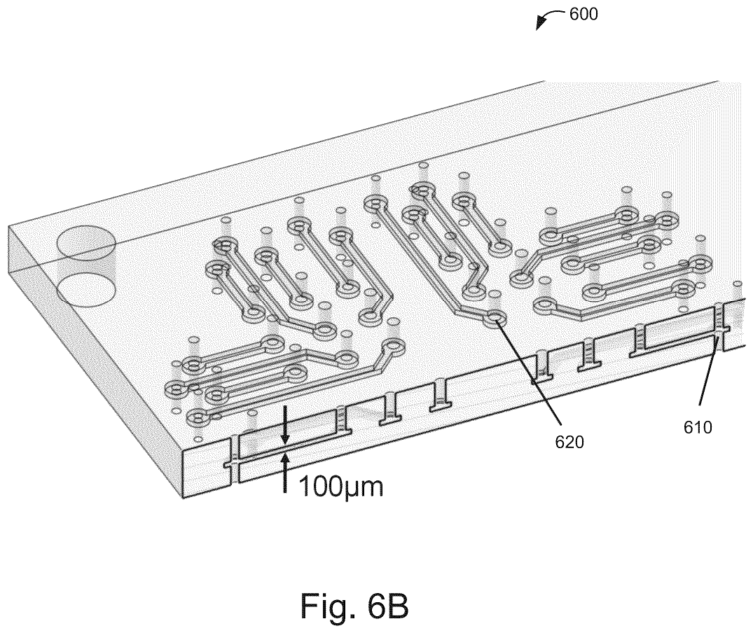

FIGS. 6A-6B illustrate perspective views of a device design 600, in accordance with various embodiments of the presently disclosed technology. As illustrated, device design 600 may comprise metallized internal structures 610 and micro-features 620. As depicted in FIG. 6B, a respective metallized internal structure may have a diameter of 150 micrometers or less.

In certain implementations, device design 600 may comprise a design for a printed circuit board. In such implementations, metallized internal structures 610 may comprise through vias and micro-features 620 may comprise solder pads.

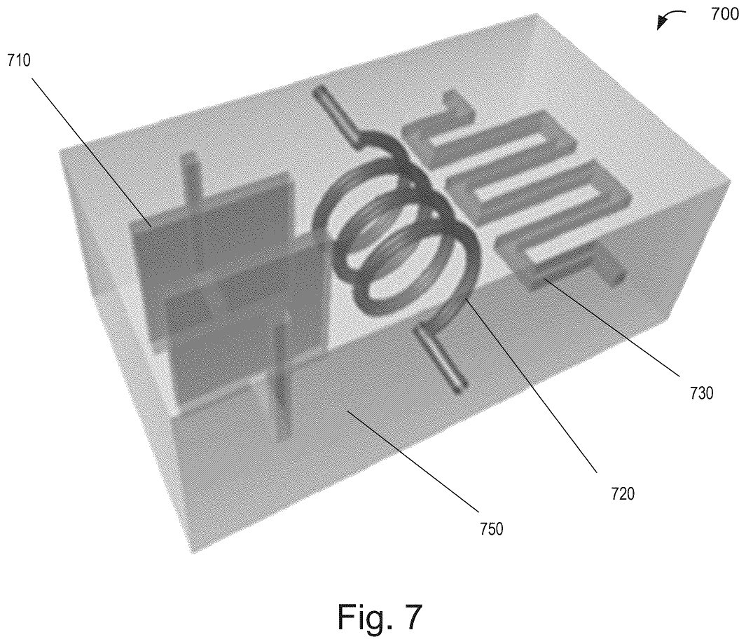

FIG. 7 illustrates an example device design 700, in accordance with various embodiments of the presently disclosed technology.

As depicted, device design 700 may comprise a substrate 750 with metallized internal electrical components embedded therein namely a capacitor 710, an inductor 720, and a resistor 730.

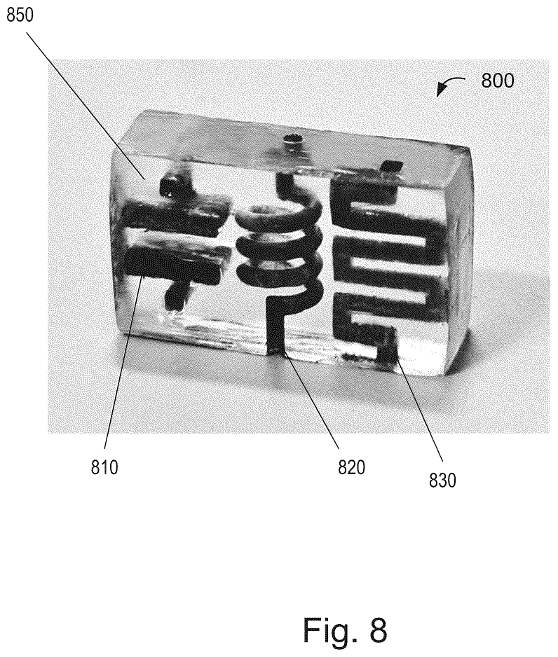

FIG. 8 illustrates a fabricated device 800 based on device design 700, in accordance with various embodiments of the presently disclosed technology.

As depicted, device 800 may comprise a substrate 850 with metallized internal electrical components embedded therein-namely a capacitor 810, an inductor 820, and a resistor 830.

Device 800 may be an example of a device fabricated using the additive manufacturing methods, and intermittent microfluidic electroless plating process disclosed herein.

As alluded to above, by combining the versatility of additive manufacturing with the precision of electroless plating, the presently disclosed fabrication methods can enable the creation of embedded elements like capacitors (e.g., capacitor 810), resistors (e.g., resistor 820), inductors (e.g., inductor 830), micro-antennas, etc. As described above, the presently disclosed fabrication techniques can facilitate heightened levels of customization and miniaturization in electronics design, significantly expanding the possibilities for future electronic devices.

Referring to capacitor 810, by utilizing the presently disclosed 3D printing process, specific regions within hollow (and subsequently metallized) internal structures can be designed to create embedded capacitors. Capacitance values can be customized by controlling the geometry and the material properties of these regions, allowing for capacitors to be seamlessly integrated into a device like device 800. Embedded capacitors can support functions like energy storage, filtering, and signal coupling, enhancing the overall performance and compactness of the device.

Referring to inductor 820, hollow internal structures can be designed in spiral or helical shapes, then metallized to form inductive elements. The inductance can be adjusted by varying the number of turns, the spacing between turns, and the cross-sectional area of the channel. These inductors can be useful in RF circuits, power management applications, and as part of tuned circuits, where precise inductance values are critical for performance.

Referring to resistor 830, resistance of metallized internal structures can be engineered by varying the thickness and material composition during the presently disclosed intermittent microfluidic electroless plating process. For example, thinner metal layers or materials with higher resistivity can be used to create regions with specific resistance values. These embedded resistors can be used for current limiting, voltage division, or as part of sensing circuits, offering precise and stable performance.

By designing hollow (and subsequently metallized) internal structures into specific geometries, such as loops or dipoles, micro-antennas can be fabricated directly within a substrate such as substrate 850. These antennas can operate at various frequencies, depending on their design, and can be used for wireless communication, sensing, or data transmission. The integration of antennas directly into a device can reduce the need for external components, leading to more compact and efficient designs.

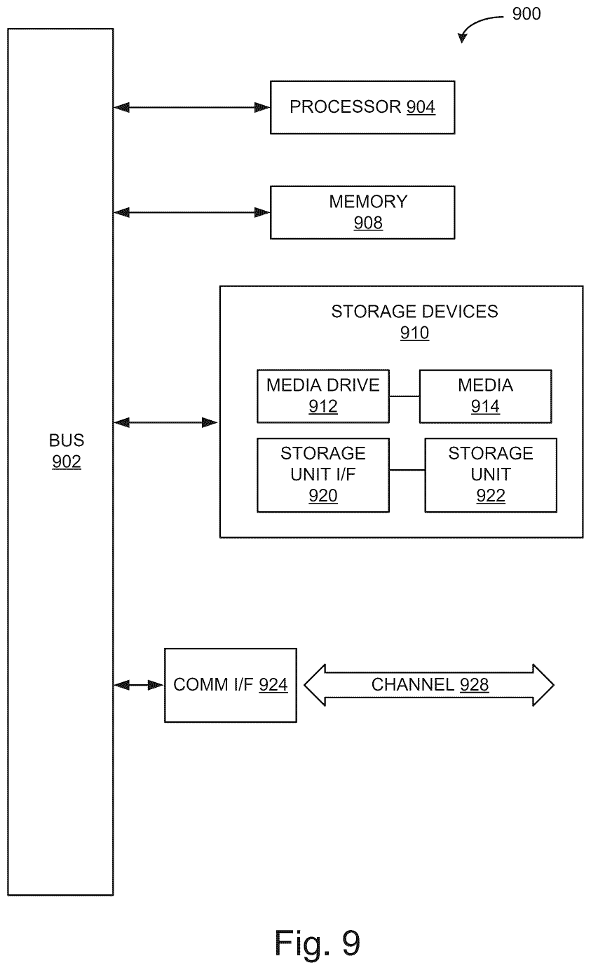

As used herein, the terms circuit and component might describe a given unit of functionality that can be performed in accordance with one or more examples of the present application. As used herein, a component might be implemented utilizing any form of hardware, software, or a combination thereof. For example, one or more processors, controllers, ASICs, PLAs, PALs, CPLDs, FPGAs, logical components, software routines or other mechanisms might be implemented to make up a component. Various components described herein may be implemented as discrete components or described functions and features can be shared in part or in total among one or more components. In other words, as would be apparent to one of ordinary skill in the art after reading this description, the various features and functionality described herein may be implemented in any given application. They can be implemented in one or more separate or shared components in various combinations and permutations. Although various features or functional elements may be individually described or claimed as separate components, it should be understood that these features/functionality can be shared among one or more common software and hardware elements. Such a description shall not require or imply that separate hardware or software components are used to implement such features or functionality.

Where components are implemented in whole or in part using software (e.g., controller 530 from FIG. 5), these software elements can be implemented to operate with a computing or processing component capable of carrying out the functionality described with respect thereto. One such example computing component is shown in FIG. 9. Various examples are described in terms of this example-computing component 900. After reading this description, it will become apparent to a person skilled in the relevant art how to implement the application using other computing components or architectures.

Referring now to FIG. 9, computing component 900 may represent, for example, computing or processing capabilities found within a self-adjusting display, desktop, laptop, notebook, and tablet computers. They may be found in hand-held computing devices (tablets, PDA's, smart phones, cell phones, palmtops, etc.). They may be found in workstations or other devices with displays, servers, or any other type of special-purpose or general-purpose computing devices as may be desirable or appropriate for a given application or environment. Computing component 900 might also represent computing capabilities embedded within or otherwise available to a given device. For example, a computing component might be found in other electronic devices such as, for example, portable computing devices, and other electronic devices that might include some form of processing capability.

Computing component 900 might include, for example, one or more processors, controllers, control components, or other processing devices. Processor 904 might be implemented using a general-purpose or special-purpose processing engine such as, for example, a microprocessor, controller, or other control logic. Processor 904 may be connected to a bus 902. However, any communication medium can be used to facilitate interaction with other components of computing component 900 or to communicate externally.

Computing component 900 might also include one or more memory components, simply referred to herein as main memory 908. For example, random access memory (RAM) or other dynamic memory, might be used for storing information and instructions to be executed by processor 904. Main memory 908 might also be used for storing temporary variables or other intermediate information during execution of instructions to be executed by processor 904. Computing component 900 might likewise include a read only memory (“ROM”) or other static storage device coupled to bus 902 for storing static information and instructions for processor 904.

The computing component 900 might also include one or more various forms of information storage mechanism 910, which might include, for example, a media drive 912 and a storage unit interface 920. The media drive 912 might include a drive or other mechanism to support fixed or removable storage media 914. For example, a hard disk drive, a solid-state drive, a magnetic tape drive, an optical drive, a compact disc (CD) or digital video disc (DVD) drive (R or RW), or other removable or fixed media drive might be provided. Storage media 914 might include, for example, a hard disk, an integrated circuit assembly, magnetic tape, cartridge, optical disk, a CD or DVD. Storage media 914 may be any other fixed or removable medium that is read by, written to or accessed by media drive 912. As these examples illustrate, the storage media 914 can include a computer usable storage medium having stored therein computer software or data.

In alternative examples, information storage mechanism 910 might include other similar instrumentalities for allowing computer programs or other instructions or data to be loaded into computing component 900. Such instrumentalities might include, for example, a fixed or removable storage unit 922 and an interface 920. Examples of such storage units 922 and interfaces 920 can include a program cartridge and cartridge interface, a removable memory (for example, a flash memory or other removable memory component) and memory slot. Other examples may include a PCMCIA slot and card, and other fixed or removable storage units 922 and interfaces 920 that allow software and data to be transferred from storage unit 922 to computing component 900.

Computing component 900 might also include a communications interface 924. Communications interface 924 might be used to allow software and data to be transferred between computing component 900 and external devices. Examples of communications interface 924 might include a modem or softmodem, a network interface (such as Ethernet, network interface card, IEEE 802.XX or other interface). Other examples include a communications port (such as for example, a USB port, IR port, RS232 port Bluetooth® interface, or other port), or other communications interface. Software/data transferred via communications interface 924 may be carried on signals, which can be electronic, electromagnetic (which includes optical) or other signals capable of being exchanged by a given communications interface 924. These signals might be provided to communications interface 924 via a channel 928. Channel 928 might carry signals and might be implemented using a wired or wireless communication medium. Some examples of a channel might include a phone line, a cellular link, an RF link, an optical link, a network interface, a local or wide area network, and other wired or wireless communications channels.

In this document, the terms “computer program medium” and “computer usable medium” are used to generally refer to transitory or non-transitory media. Such media may be, e.g., memory 908, storage unit 920, media 914, and channel 928. These and other various forms of computer program media or computer usable media may be involved in carrying one or more sequences of one or more instructions to a processing device for execution. Such instructions embodied on the medium, are generally referred to as “computer program code” or a “computer program product” (which may be grouped in the form of computer programs or other groupings). When executed, such instructions might enable the computing component 900 to perform features or functions of the present application as discussed herein.

It should be understood that the various features, aspects and functionality described in one or more of the individual examples are not limited in their applicability to the particular example with which they are described. Instead, they can be applied, alone or in various combinations, to one or more other examples, whether or not such examples are described and whether or not such features are presented as being a part of a described example. Thus, the breadth and scope of the present application should not be limited by any of the above-described exemplary examples.

Terms and phrases used in this document, and variations thereof, unless otherwise expressly stated, should be construed as open ended as opposed to limiting. As examples of the foregoing, the term “including” should be read as meaning “including, without limitation” or the like. The term “example” is used to provide exemplary instances of the item in discussion, not an exhaustive or limiting list thereof. The terms “a” or “an” should be read as meaning “at least one,” “one or more” or the like; and adjectives such as “conventional,” “traditional,” “normal,” “standard,” “known.” Terms of similar meaning should not be construed as limiting the item described to a given time period or to an item available as of a given time. Instead, they should be read to encompass conventional, traditional, normal, or standard technologies that may be available or known now or at any time in the future. Where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “component” does not imply that the aspects or functionality described or claimed as part of the component are all configured in a common package. Indeed, any or all of the various aspects of a component, whether control logic or other components, can be combined in a single package or separately maintained and can further be distributed in multiple groupings or packages or across multiple locations.

Additionally, the various examples set forth herein are described in terms of exemplary block diagrams, flow charts and other illustrations. As will become apparent to one of ordinary skill in the art after reading this document, the illustrated examples and their various alternatives can be implemented without confinement to the illustrated examples. For example, block diagrams and their accompanying description should not be construed as mandating a particular architecture or configuration.

What is claimed is:

1. A method comprising:
using a 3D printer to print a device comprising hollow internal structures; and
applying an intermittent microfluidic electroless plating process to the device to coat the hollow internal structures with metal, wherein applying the intermittent microfluidic electroless plating process to the device comprises placing the device in a mold and while the device is in the mold:
(a) introducing a first cycle of plating solution through an inlet of the mold,
(b) pumping the first cycle of plating solution through the hollow internal structures,
(c) pausing the pumping of the first cycle of plating solution;
(d) introducing a second cycle of plating solution through the inlet of the mold to displace the first cycle of plating solution out an outlet of the mold;
(e) pumping the second cycle of plating solution through the hollow internal structures,
(f) pausing the pumping of the second cycle of plating solution, and
(g) introducing a third cycle of plating solution through the inlet of the mold to displace the second cycle of plating solution out the outlet of the mold.

2. The method of claim 1, wherein applying the intermittent microfluidic electroless plating process to the device further comprises repeating steps (a)-(g) with subsequent cycles of fresh plating solution for at least 30 minutes.

3. The method of claim 1, wherein:
using the 3D printer to print the device comprises using the 3D printer to print the device from a dual-curing resin by curing the dual-curing resin with ultraviolet (UV) radiation during the printing; and
the method further comprises curing the device with thermal radiation after the printing.

4. The method of claim 3, wherein the dual-curing resin comprises:
a photoinitiator that creates reactive species when exposed to the UV radiation; and
a thermal initiator that creates reactive species when exposed to the thermal radiation.

5. The method of claim 4, wherein the dual-curing resin further comprises:
an acrylate oligomer comprising 40-60% of the dual-curing resin by weight;
one or more crosslinking agents comprising 12-20% of the dual-curing resin by weight;
one or more additives comprising 20-40% of the dual-curing resin by weight, wherein the one or more additives comprise silica and a reactive diluent; and
a UV blocker comprising 0.5% or lower of the dual-curing resin by weight;
wherein, the photoinitiator comprises 1-3% of the dual-curing resin by weight and the thermal initiator comprises 0.5% or lower of the dual-curing resin by weight.

6. The method of claim 3, wherein curing the device with thermal radiation comprises:
placing the device in a second mold; and
applying the thermal radiation to the second mold.

7. The method of claim 1, further comprising, before applying the intermittent microfluidic electroless plating process to the device:
(i) immersing the device in an etching solution to increase surface roughness of the hollow internal structures;
(ii) rinsing the device to remove excess etching solution;
(iii) immersing the device in a sensitization solution to cause sensitization cations to be absorbed onto surfaces of the hollow internal structures;
(iv) rinsing the device to remove excess sensitization solution;
(v) immersing the device in an activation solution to cause activation cations to replace the sensitization cations on the surfaces of the hollow internal structures;
(vi) rinsing the device to remove excess activation solution; and
(vii) repeating steps (iii)-(v).

8. The method of claim 7, wherein:
the etching solution comprises an alkaline solution;
the sensitization solution comprises a SnCl₂ solution and the sensitization cations comprise Sn²⁺ ions; and
the activation solution comprises a PdCl₂ solution and the activation cations comprise Pd²⁺ ions.

9. The method of claim 8, wherein:
concentration of SnCl₂ in the SnCl₂ solution is between 0.1 M and 0.2 M; and
concentration of PdCl₂ in the PdCl₂ solution is between 0.001 M and 0.005 M.

10. The method of claim 1, further comprising, after applying the intermittent microfluidic electroless plating process to the device:
removing the plated device from the mold;
pushing deionized water through the hollow internal structures to remove excess plating solution; and
pushing compressed air through the hollow internal structures to dry the plated hollow internal structures.

11. The method of claim 1, wherein the plating solution comprises:
a metal compound;
a reducing agent;
a chelating agent; and
an inhibitor agent.

12. The method of claim 11, wherein:
the metal comprises a copper-based compound;
the reducing agent comprises glyoxylic acid;
the chelating agent comprises ethylenediaminetetraacetic acid (EDTA); and
the inhibitor agent comprises 2,2′-Bipyridine.

13. The method of claim 11, wherein pH of the plating solution is between 12.0 and 13.0.

14. The method of claim 1, wherein:
pumping the first cycle of plating solution through the hollow internal structures comprises pumping the first cycle of plating solution for between 5 and 30 seconds; and
pausing the pumping of the first cycle of plating solution comprises pausing the pumping of the first cycle of plating solution for between 10 and 60 seconds.

15. The method of claim 1, wherein pumping the first cycle of plating solution through the hollow internal structures comprises using a peristaltic pump fluidly connected to the mold.

16. The method of claim 1, wherein a respective hollow internal structure comprises a diameter of 150 micrometers or less.

17. A method comprising:
using a 3D printer to print an electronic device comprising embedded microchannels from a dual-curing resin, wherein using the 3D printer to print the electronic device comprises curing the dual-curing resin with ultraviolet (UV) radiation during the printing;
curing the printed electronic device with thermal radiation;
applying an intermittent microfluidic electroless plating process to the dual-cured electronic device to coat the embedded microchannels with metal, wherein applying the intermittent microfluidic electroless plating process to the dual-cured electronic device comprises placing the dual-cured electronic device in a mold and while the dual-cured electronic device is in the mold:
(a) introducing a first cycle of plating solution through an inlet of the mold,
(b) pumping the first cycle of plating solution through the embedded microchannels,
(c) pausing the pumping of the first cycle of plating solution,
(d) introducing a second cycle of plating solution through the inlet of the mold to displace the first cycle of plating solution out an outlet of the mold;
(e) repeating steps (a)-(d) with subsequent cycles of fresh plating solution.

18. A microfluidic electroless plating system comprising:
a fluidly sealed mold;
a pump fluidly connected to the fluidly sealed mold; and
a controller communicatively connected to the pump, the controller comprising one or more processors and memory storing machine-readable instructions that, when executed by the one or more processors, cause the microfluidic electroless plating system to:
(a) introduce a first cycle of plating solution through an inlet of the fluidly sealed mold,
(b) push, via the pump, the first cycle of plating solution through embedded microchannels of a device placed within the fluidly sealed mold for between 5 and 30 seconds,
(c) pause the pumping of the first cycle of plating solution for between 10 and 60 seconds,
(d) introduce a second cycle of plating solution through an inlet of the fluidly sealed mold to displace the first cycle of plating solution out an outlet of the fluidly sealed mold,
(e) push, via the pump, the second cycle of plating solution through the embedded microchannels of the device for between 5 and 30 seconds,
(f) pause the pumping of the second cycle of plating solution for between 10 and 60 seconds, and
(g) introduce a third cycle of plating solution through the inlet of the fluidly sealed mold to displace the second cycle of plating solution out the outlet of the fluidly sealed mold.

19. The microfluidic electroless plating system of claim 18, wherein the memory stores further machine-readable instructions that, when executed by the one or more processors, cause the microfluidic electroless plating system to:
repeat steps (a)-(g) with subsequent cycles of plating solution for at least 30 minutes.

20. The microfluidic electroless plating system of claim 18, wherein a respective embedded microchannel comprises a diameter of 150 micrometers or less.
